(19) United States
(12) Patent Application Publication
(10) Pub. No.: US 2020/0273811 A1
(43) Pub. Date: Aug. 27, 2020

(54) IC DIE PACKAGE THERMAL SPREADER AND EMI SHIELD COMPRISING GRAPHITE

(71) Applicant: Intel Corporation, Santa Clara, CA (US)

(72) Inventors: Debendra Mallik, Chandler, AZ (US); Mitul Modi, Phoenix, AZ (US); Sanka Ganesan, Chandler, AZ (US); Edvin Cetegen, Chandler, AZ (US); Omkar Karhade, Chandler, AZ (US); Ravindranath Mahajan, Chandler, AZ (US); James C. Matayabas, Jr., Gilbert, AZ (US); Jan Krajniak, Phoenix, AZ (US); Kumar Singh, Phoenix, AZ (US); Aastha Uppal, Chandler, AZ (US)

(73) Assignee: Intel Corporation, Santa Clara, CA (US)

(21) Appl. No.: 16/287,665

(22) Filed: Feb. 27, 2019

(51) Int. Cl. H01L 23/552; H01L 23/31; H01L 23/29; H01L 23/34; H01L 23/00; H01L 21/56; H01L 23/532

(52) U.S. Cl. CPC H01L 23/552; H01L 23/3114; H01L 23/3128; H01L 23/29; H01L 23/34; H01L 23/53228; H01L 24/17; H01L 24/97; H01L 21/565; H01L 21/561; H01L 24/09

(57) ABSTRACT

IC package including a material preform comprising graphite. The material preform may have a thermal conductivity higher than that of other materials in the package and may therefore mitigate the formation of hot spots within an IC die during device operation. The preform may have high electrical conductivity suitable for EMI shielding. The preform may comprise a graphite sheet that can be adhered to a package assembly with an electrically conductive adhesive, applied, for example over an IC die surface and a surrounding package dielectric material. Electrical interconnects of the package may be coupled to the graphite sheet as an EMI shield. The package preform may be grounded to a reference potential through electrical interconnects of the package, which may be further coupled to a system-level ground plane. System-level thermal solutions may interface with the package-level graphite sheet.

### BACKGROUND

In electronics manufacturing, integrated circuit (IC) packaging is a stage of semiconductor device fabrication, in which an IC that has been fabricated on a die (or chip) comprising a semiconducting material is encapsulated in a “package” that can protect the IC from physical damage and support electrical contacts that connect the IC to a host circuit board or another system component. In the IC industry, the process of fabricating a package is often referred to as packaging.

Electro-magnetic interference (EMI) shielding of IC packages used in communication devices is important for signal integrity, and for enabling increasingly more compact systems. EMI shielding typically requires application of metal containers (e.g., cans), or various forms of conformal shielding. A solid metal can-shield may be soldered to a substrate/PCB to sit over the EMI inducing/sensitive IC. A conformal shield may be in the form of a sputtered metal (e.g., thin layer of Cu over a Ti seed layer), or a sprayed composite comprising a conductive filler. Alternatively, a Faraday cage may be directly integrated within a IC die package through a network of wirebonds, which may be encapsulated in mold material during standard package assembly. Metal film sputtering requires a significant capital investment, increasing IC die package costs. Spray shielding is also expensive due to high material cost (driven by the cost of fillers). Wirebond formation and can-shielding are time-consuming and also require a larger footprint.

Along with the need for EMI shielding, the power density of integrated circuits continues to increase. Many new technologies, such as 5G wireless technology, will further exacerbate package thermal management issues because of higher frequency operation and higher up-time. This problem is particularly challenging with the extremely small IC die (e.g., 1-3 mm die edge length) that are often employed in RF applications. Within these small IC die there may be highly localized power generation (e.g., within a signal amplifier circuit or RF filtering circuit) where the power density is very high, which can lead to localized temperatures well above typical junction temperature targets.

For some small-die package architectures, such as a flip-chip chip scale package (FC-CSP), heat spreading over a back (top) side of an IC die is limited. For example, a mold material that might encapsulate the package typically has a thermal conductivity of only around 2.5 W/mK, or less. As such, in some exposed die mold (EDM) packages, the top side of the die may be left exposed so that system-level thermals can interface with the IC die backside more directly. Additional thermal solutions such as gap pads or thermal interface materials (TIMs) are then applied at the package or system level. These materials offer limited thermal conductivities and this standard approach is becoming increasingly more difficult to execute for thinner packages with decreasing footprints.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels are repeated among the figures to indicate corresponding or analogous elements. In the figures:

FIG. 1A, 1B, and 1C illustrate cross-sectional views of IC packages including an EMI shielding heat spreader comprising graphite, in accordance with some embodiments;

FIG. 2A and 2B illustrate plan views of IC packages including an EMI shielding heat spreader comprising graphite, in accordance with some embodiments;

FIG. 3A and 3B illustrate cross-sectional views of an interface between a conductive adhesive and a surface of IC chip within an IC package, in accordance with some embodiments;

FIG. 4A illustrates a plan view of an IC package including an EMI shielding heat spreader comprising a patterned graphite sheet with embedded features, in accordance with some embodiments;

FIG. 4B illustrates a cross sectional view of the IC package shown in FIG. 4A, in accordance with some embodiments;

FIG. 5 illustrates a flow diagram of methods for assembling an IC package including an EMI shielding heat spreader comprising graphite, in accordance with some embodiments;

FIG. 6 is a functional block diagram of an electronic computing device, in accordance with some embodiments; and

FIG. 7 illustrates a mobile computing platform and a data server machine employing an IC package including an EMI shielding heat spreader comprising graphite, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Examples of IC packages including an electrically coupled heat spreading material comprising crystalline carbon are described herein. The sheet of heat spreading material comprising crystalline carbon may have a high thermal conductivity, and have sufficient electrical conductivity to further function as an EMI shield for one or more IC dies with the IC package. The heat spreading material may be assembled as a preform or sheet during package assembly process, subsequent to an application, or build-up, of packaging material. The sheet of heat spreading material may be physically coupled to an IC die surface by an adhesive, and high thermal conductivity of heat spreading material may reduce formation of hot spots during IC device operation.

In some advantageous embodiments described further below, a heat spreading material sheet may be electrically coupled to a reference voltage rail of the IC package. In some embodiments, adhesive between the sheet of heat spreading material and the IC die has sufficient electrical conductivity to interconnect the heat spreading material to the reference voltage rail of the IC package. For embodiments where the sheet of heat spreading material is electrically coupled to the IC package, the sheet of heat spreading material may be operable as a component of a package-level EMI shield. This package-level EMI shield may help protect IC die within the IC package from sources of EMI external of the IC package, and/or help protect components external of the IC package from EMI generated by IC die within the IC package.

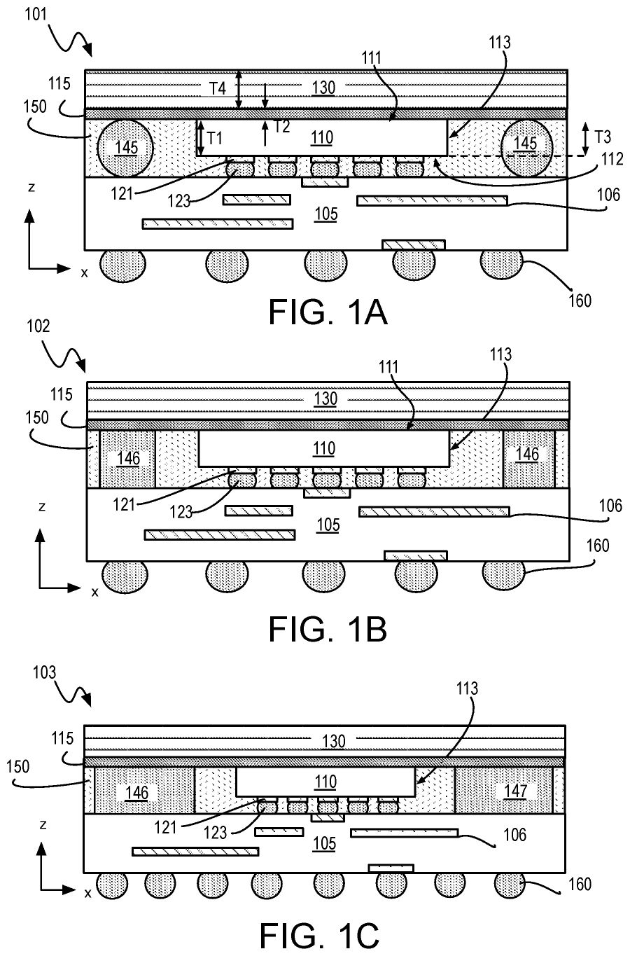

An IC package in accordance with some embodiments includes a sheet of heat spreading material adhered to a surface of an IC die. FIG. 1A illustrates a cross-sectional view of an IC package 101 that includes a sheet of heat spreading material 130 over a surface of an IC die 110, in accordance with some embodiments. The sheet of heat spreading material 130 is to enhance the spread of heat laterally over the area of IC die 110 (e.g., reduce thermal gradients on surface 111). In this example, the sheet of heat spreading material 130 is over a top (back) side of IC die 110 with an interface material layer 115 between the sheet of heat spreading material 130 and an IC die back side surface 111. Back side surface 111 may comprise a crystalline semiconductor, such as silicon, or an alloy thereof (e.g., SiGe), germanium, a III-V semiconductor alloy, or the like. One or more IC dielectric thin films (SiO, SiN, SiON, etc.), for example deposited following a wafer thinning process may also be present on back side surface 111.

In the illustrated example, IC package 101 is a flip-chip package in which a front (bottom) side IC die surface 112 has metallization features 121. Front-side metallization features 121 are coupled through solder features 123 to an underlying interposer, substrate or package material 105. Metallization features 121 may be a top interconnect level of IC die 110, for example, and a single feature may comprise a pad, post, pillar, or other metal structure. Solder features 123 may be solder bumps or microbumps, for example. Package material 105 may further comprise one or more metallized redistribution or fan out layers 106 that further couple electrical metallization features 121 to package interconnects that are suitable for surface mounting package 101 to a system-level component, such as a printed circuit board (not depicted). In the illustrated example, metallization 106 is coupled to solder features 160 (e.g., bumps or balls). Solder features 160 may be of larger in diameter (e.g., hundreds of μm) than solder features 123 (e.g., less than 100 μm). Solder features 160 may, be solder balls, for example, while solder features 123 may be bumps derived from a solder paste, for example.

IC die 110 is over a center portion of package material 105 while another package material 150 is over a perimeter, or edge, portion of package material 105. IC die 110 is at least partially encapsulated within package material 150, with package material 150 being adjacent to an IC die edge sidewall 113, for example as a result of package material 150 having been molded around IC die 110. Package material 150 may have a relatively low electrical conductivity, with package material 150 advantageously being a dielectric. In some exemplary embodiments, package material 150 comprises a cured (e.g., thermoset) resin or polymer comprising epoxy and/or silicone. Package material 150 may be any alternative material known to be suitable for IC die packaging applications. In some embodiments, package material 150 has a relatively low bulk thermal conductivity (e.g., less than 5 W/mK), and may, for example, have a bulk thermal conductivity in the range of 1-3 W/(mK).

As shown in FIG. 1A, package material 150 has a z-thickness T3, from IC die front surface 112, that is substantially equal to IC die thickness T1. Such an architecture is indicative of the sheet of heat spreading material 130 being integrated into an exposed die mold (EDM) packaging process, for example. IC die thicknesses T1 may vary, but in some examples is 100-250 μm. IC die 110 may include one or more integrated circuits. In some embodiments, IC die 110 includes one or more of: power management circuitry (a PMIC), radio frequency communication circuitry (RFIC), microprocessor circuitry (e.g., application processors, central processors, graphics processors), or memory circuitry (e.g., DRAM, MRAM, RRAM, etc.). In some further embodiments, IC die 110 includes System on a Chip (SoC) circuitry that may further integrate two or more of the above circuitries. Although the illustrated example shows only one IC die 110, which is typical for small form factor packaging embodiments, it is noted that embodiments of the invention may also be applicable to multi-die packages, as well as significantly larger package form factors.

The sheet of heat spreading material 130 has a thickness T4 that is sufficient to permit its handling and placement during a package assembly process. In some embodiments, heat spreading material thickness T4 is less than the IC die thickness T1 (e.g., 10-50% of IC die thickness T2). In other embodiments, heat spreading material thickness T4 is at least the IC die thickness T1, and may even be significantly thicker than the IC die thickness T1 (e.g., 2-3 times T1).

The sheet of heat spreading material 130 has a higher thermal conductivity, at least within a plane of IC die 110 (e.g., x-y plane), than that of package material 150. While package material 150 may have a relatively low thermal conductivity (e.g., less than 5 W/mK), the sheet of heat spreading material 130 has a relatively high thermal conductivity (e.g., exceeding at least 100 W/mK, and advantageously exceeding 400 W/mK). In some embodiments, the sheet of heat spreading material 130 is of a composition that has anisotropic thermal conductivity, for example having a higher thermal conductivity within the x-y plane than along the z-dimension. In further embodiments, the sheet of heat spreading material 130 also has a higher electrical conductivity, at least within a plane of IC die 110 (e.g., x-y plane), than that of package material 150.

In accordance with some embodiments, the sheet of heat spreading material 130 has a composition including crystalline carbon. The sheet of heat spreading material 130 may be a composite or substantially homogenous. In some embodiments, the sheet of heat spreading material 130 comprises predominantly crystalline carbon, which may be in the form of a substantially pure graphite sheet. For graphite sheet embodiments, the graphite may comprise a stack of 2D atomic layers oriented to have a dominant orientation (i.e., texture) that is parallel to the x-y plane, as represented in FIG. 1A by the horizontal field lines shading 130. Thermal conductivity, as well as electrical conductivity, may then be higher within the x-y plane of heat spreading material 130 than in the z-dimension of heat spreading material 130.

In some embodiments, an interface material is between a sheet of heat spreading material comprising graphite and an underlying package material and/or IC die surface. The interface material may physically, and/or thermally, and/or electrically couple the sheet of heat spreading material to the IC die and/or other portions of the IC package. In the illustrated embodiments, interface material 115 has gap-filling properties to accommodate IC die surface 111, and/or a surface of heat spreading material 130. Interface material 115 has a material thickness T2, as measured in a direction substantially normal to IC die surface 111. Material thickness T2 may vary, but it may be advantageous to minimize material thickness T2, for example to reduce thermal resistance and/or electrical resistance between heat spreading material 130 and an underlying surface. A greater material thickness T1 may be more acceptable where interface material 115 has higher thermal and/or electrical conductivity. In some embodiments, material thickness T1 is less than about 100 μm. In some such embodiments, material thickness T1 is less than material thickness T4. Material thickness T1 may be as little as 5-15 μm where a chemical deposition or wet coating process (e.g., spray, etc.) is employed to apply interface material 115 over IC die surface 111 and over adjacent package material 150. Material thickness T1 may be 30 μm, or more, where an adhesive film application process is employed to apply interface material 115.

In some embodiments, interface material 115 has thermal conductivity exceeding that of package material 150. Interface material 115 may have a thermal conductivity somewhere between that of package material 150 and that of sheet of heat spreading material 130, for example. In some advantageous embodiments, interface material 115 has thermal conductivity of at least 4 W/mK, advantageously more than 8 W/mK, and more advantageously between 8 W/mK and 20 W/mK. In some further embodiments, interface material 115 also has an electrical conductivity exceeding that of package material 150. Interface material 115 may have an electrical conductivity somewhere between that of package material 150 and the sheet of heat spreading material 130, for example. In some embodiments, interface material 115 is a composite material comprising particles of a metal, such as silver, copper, or gold, for example, within a matrix material. The matrix material may be a dielectric where the content of the metal particles is sufficient to achieve a suitably high thermal and electrical conductivity for the composite. For some composite embodiments, the metal content exceeds 50%. In some specific embodiments, the matrix material comprises a thermoset resin (epoxy), or a silicone-based polymer (e.g., polysiloxanes including predominantly silicon, oxygen, and carbon), which may be fully cured after the assembly of the sheet of heat spreading material 130, for example.

In some embodiments, at least one of the interface material and the sheet of heat spreading material is in contact with an electrical interconnect of an IC package. The electrical interconnect, may for example, be at a predetermined package reference voltage and/or controllable package bias voltage. In some examples, the electrical interconnect is to be at a ground rail (plane) of the IC package. Contact to this electrical interconnect is to electrically tie the sheet of heat spreading material to the voltage of the electrical interconnect. The sheet of heat spreading material may therefore be operable as a component of an EMI shield that extends over IC die surface 111. As further shown in FIG. 1A, a portion of interface material 115 is between the sheet of heat spreading material 130 and a solder feature 145 located at the periphery of IC package 101. This portion of interface material 115 is in contact with solder features 145 and electrically couples solder feature 145 to the sheet of heat spreading material 130. Solder feature 145 is a through-package electrical interconnect passing through package material 150. Solder feature 145 may be, for example, a solder bump or ball, which may have substantially the same composition as solder feature 123, albeit of greater z-height and/or diameter. Solder feature 145 is further in contact with a metallization level 106 of package material 105. That metallization level 106 may electrically couple solder feature 145 to the package ground plane, for example. Solder feature 145 may therefore also form a portion of a package-level EMI shield, along with the sheet of heat spreading material 130.

FIG. 1B illustrates a cross-sectional view of an IC package 102, in accordance with some alternative embodiments. Reference labels from IC package 101 (FIG. 1A) are repeated in IC package 102 (FIG. 1B) to indicate analogous elements, which may have any of the same attributes described above. In package 102, the sheet of heat spreading material 130 is electrically coupled to a reference voltage plane of IC package 102 through metallization extending from package material 105. For such embodiments, electrical interconnect between the sheet of heat spreading material 130 is through contact between interface material 115 and a protruding interconnect metallization feature 146. Solder feature(s) may therefore be absent from the periphery of IC package 102. In some embodiments, interconnect metallization feature 146 is a pillar or trace. Interconnect metallization feature 146 may have substantially the same composition as metallization levels 106. For example, interconnect metallization feature 146 may comprise copper (e.g., an alloy thereof). In package 102, package material 150 is adjacent to a sidewall of interconnect metallization feature 146. A top surface of interconnect metallization feature 146 is substantially co-planar with IC die surface 111.

FIG. 1C is a cross-sectional view of an IC package 103, in accordance with some alternative embodiments. Reference labels from IC packages 101(FIG. 1A) and 102 (FIG. 1B) are repeated in IC package 103 (FIG. 1C) to indicate analogous elements, which may have any of the same attributes described above in the context of IC package 101 (FIG. 1A). In package 103, the sheet of heat spreading material 130 is electrically coupled to a reference voltage plane of IC package 102 through a package stiffener 147 that is between package material 105 and sheet of heat spreading material 130 within a peripheral region of of IC package 102. For such embodiments, electrical coupling between the sheet of heat spreading material 130 is through contact between interface material 115 and package stiffener 146. Solder feature(s) may therefore be absent from the periphery of IC package 103. In some such embodiments, package stiffener 147 comprises a metal other than that of metallization level 106, and may, for example, comprise iron (e.g., where package stiffener 146 is a stainless steel). In package 103, package material 150 is adjacent to a sidewall of package stiffener 147. A top surface of package stiffener 147 is substantially co-planar with IC die surface 111.

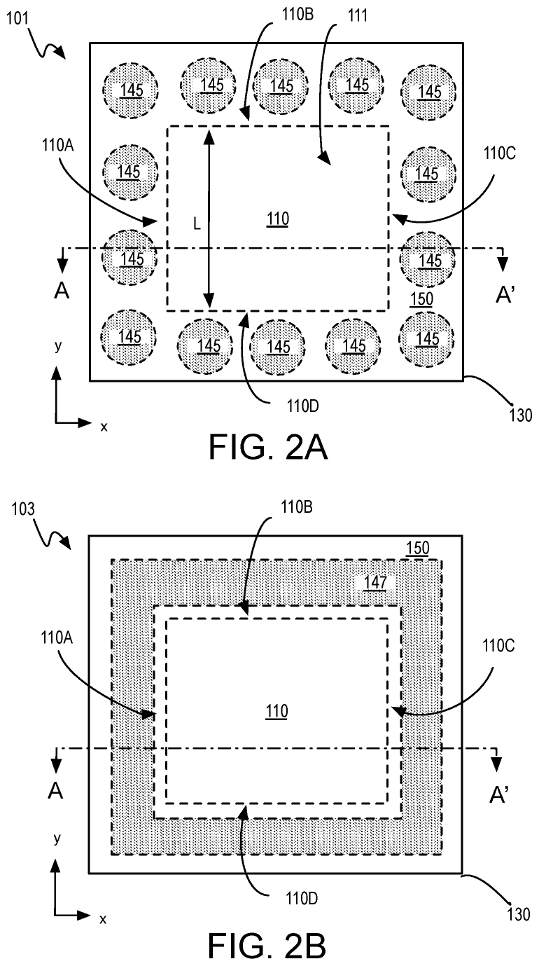

FIG. 2A illustrates a plan view of IC package 101, in accordance with some embodiments. The A-A′ line shown in FIG. 2A is included as a reference to the location of the cross-sectional view that was shown in FIG. 1A. Reference labels from IC package 101 are repeated in FIG. 2A to indicate analogous elements, which may have any of the same attributes described above in the context of FIG. 1A. In accordance with some embodiments, IC die has an area of no more than 100 mm², and die edge length L may vary from 1-10 mm, for example. As shown in FIG. 2A, a plurality of solder features 145 are spaced apart along a perimeter of IC die 110, surrounding four IC die sidewalls 110A, 110B, 110C and 110D. With each of solder features 145 electrically coupled to the sheet of heat spreading material 130, an EMI shield encompasses five sides (sidewalls 110A-110D and surface 111) of IC die 110.

FIG. 2B illustrates a plan view of IC package 103, in accordance with some embodiments. The A-A′ line shown in FIG. 2C is included as a reference to the location of the cross-sectional view that was shown in FIG. 1C. Reference labels from IC package 103 are repeated in FIG. 2B to indicate analogous elements, which may have any of the same attributes described above in the context of FIG. 1C. As shown in FIG. 2B, a package stiffener 147 continuously encloses multiple sides of IC die 101. In the specific example illustrated, package stiffener 147 completely encloses IC die 110, forming a continuous perimeter surrounding four IC die sidewalls 110A, 110B, 110C and 110D. An EMI shield including the sheet of heat spreading material 130 and package stiffener 147 therefore encompasses five sides (sidewalls 110A-110D and surface 111) of IC die 110.

For IC packages where a sheet of heat spreading material is adhered to package metallization protrusions (e.g., IC package 102 shown FIG. 1B), the protruding interconnect metallization may comprise a plurality of metallization features (e.g., pillars) about a perimeter of the package, substantially as illustrated for solder features 145 in FIG. 2A. Alternatively, the interconnect metallization protrusion may comprise single metallization feature (e.g., trace) that continuously surrounds an IC die, for example substantially as illustrated for package stiffener 147 in FIG. 2B.

In the embodiments illustrated by FIG. 2A-2B, as well as FIG. 1A-1C, the sheet of heat spreading material 130 has an area larger than that of the IC die. In some embodiments, heat spreading material 130 has substantially the same area as that of package materials 150 and 105 with a sidewall of the sheet of heat spreading material 130 being coincident with a sidewall of package material 105, as well as a sidewall of package material 150. Interface material 130 likewise occupies substantially the same package area with a sidewall of interface material 130 being coincident with a sidewall of package material 150 and a sidewall of the sheet of heat spreading material 130. Sidewall continuity of these various packaging constituent materials is indicative of the sheet of heat spreading material 130 having been applied in a package assembly process prior to singulation of the IC package. IC package singulation may be defined as a package sidewall that intersects each of the sheet of heat spreading material 130, interface material 115, package material 105 and package material 150.

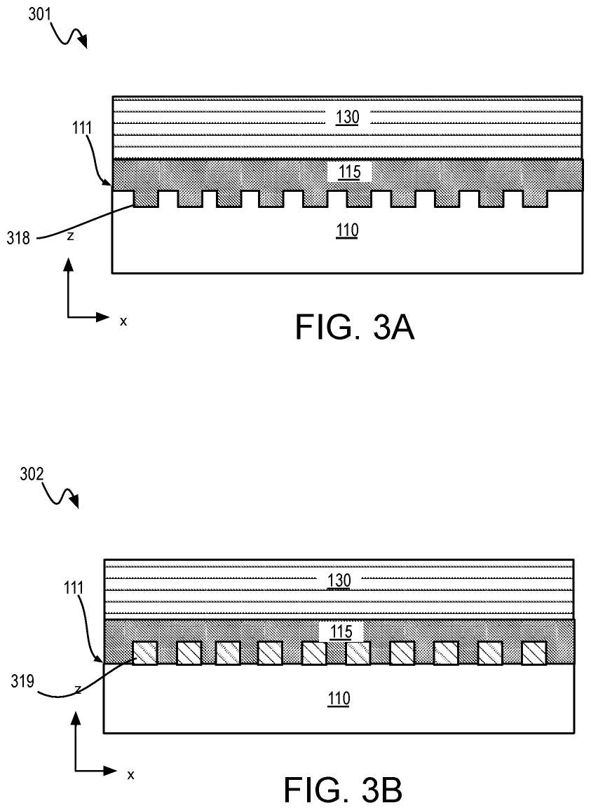

In some embodiments, a surface of an IC die is processed for example to reduce thermal resistance between the IC die and an interface material in contact with the IC die surface. Thermally (and electrically) conductive interface material may, for example, at least partially backfill topography of the IC die surface. Such topography may increase contact area between the adhesive and the IC die and/or may locally increase lateral heat spreading. FIG. 3A and 3B illustrate cross-sectional views of interface material 115 and IC chip surface 111, in accordance with some embodiments. Reference labels from IC package 101 are repeated in FIG. 2A and 2B to indicate analogous elements, which may have any of the same attributes described above in the context of FIG. 1A.

As shown in FIG. 3A, IC die surface 111 includes surface recesses 318. Interface material 115 is within surface recesses 318. In some embodiments, surface recesses 318 have an aspect ratio of between 1:1 and 20:1 (depth:width), and a feature size of micrometers (e.g., 1-25 μm). Surface recesses 318 may have substantially orthogonal sidewalls, for example as a result of an anisotropic semiconductor etch process performed according to a mask pattern. In other embodiments, surface recesses 318 may have an aspect ratio significantly greater than 20:1, and a feature size of nanometers (e.g., 20-200 nm). Such surface recesses may result from anodic isotropic (wet chemical) etch. Interface material 115 may at least partially backfill surface recesses 318, for example as a function of viscosity and surface wetting properties of the interface material 115.

As shown in FIG. 3B, IC die surface 111 again includes surface recesses but here the recesses are between features 319 extending from IC die 110. Interface material 115 is in contact with sidewalls of features 319. In some embodiments, features 319 have an aspect ratio of between 1:1 to 20:1 (width to height) and a feature size of micrometers (e.g., 1-25 μm). Surface features 319 may have substantially orthogonal sidewalls, for example as a result of a masked metal plating process. In other embodiments, surface features 319 may have an aspect ratio significantly greater than 20:1, and a feature size of only nanometers (e.g., 20-200 nm). Such surface features may be the result of a nanoparticle deposition process, for example. In some embodiments surface features 319 comprise a metal, such as copper, gold, silver, or aluminum.

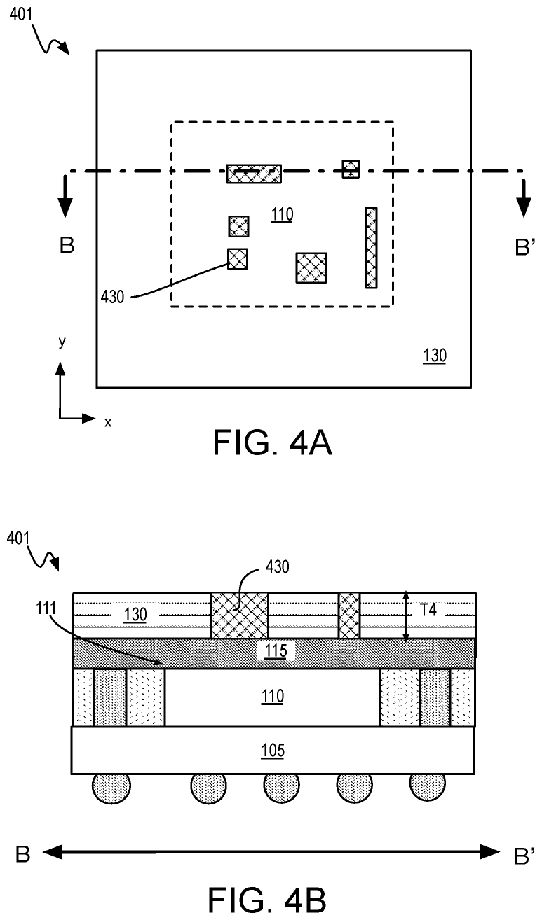

In some embodiments, one or more features are embedded with a sheet of heat spreading material. An embedded feature may have an even higher thermal and/or electrical conductivity than that of the surrounding heat spreading material. FIG. 4A illustrates a plan view of an IC package 401 that includes an EMI shielding heat spreader comprising a patterned graphite sheet with embedded features, in accordance with some embodiments. FIG. 4B illustrates a cross sectional view of IC package 401 along the B-B′ line illustrated in FIG. 4A, in accordance with some embodiments. Reference labels from IC package 101 are repeated for IC package 401 to indicate analogous elements, which may have any of the same attributes described above in the context of FIG. 1A, for example.

As shown in FIG. 4A, the sheet of heat spreading material 130 spans an entire lateral length of package 401, however within a portion of the package area overlying IC die 110 there are features 430. As further shown in FIG. 4B, features 430 are embedded within the sheet of heat spreading material 130. In the illustrated example, features 430 also have thickness T4. In alternative embodiments however, features 430 may have thicknesses less than thickness T4. Features 430 may have any lateral dimension, and may for example have micrometer diameters down to diameters of only a few hundred nanometers. Features 430 have a different material composition than that of heat spreading material 130. In some embodiments, features 430 may comprise a material having a higher thermal conductivity (in at least one dimension) than that of heat spreading material 130. In some embodiments, features 430 comprise a metal, such as, but not limited to, copper, gold, silver, or aluminum.

Features 430 may be located over predetermined regions of IC die 110. Such locations may have been computationally modeled or empirically determined to dissipate more heat than other regions of IC die 110, for example. For such embodiments, heat spreading material 130 provides a structure hosting features 430 and/or a means of integrating such features at the package level. In contrast to a metal sheet, graphite of heat spreading material 130 is relied upon for thermal and/or electrical conductivity over a majority of the IC package area. Noting a graphite sheet may have excellent heat spreading primarily in the x-y plane, features 430 may provide enhanced z-dimensional heat transfer within some local regions of package 401. To form features 430, the sheet of heat spreading material 130 may be patterned (before or after package assembly). For example, the sheet can be patterned with an opening over an anticipated hot-spot. After assembly of the sheet into the IC package, any openings within the sheet can then be at least partially filled by plating, or with a metal slug (e.g., via pick-and-place), or through application of a conductive ink (e.g., via a printing process), for example.

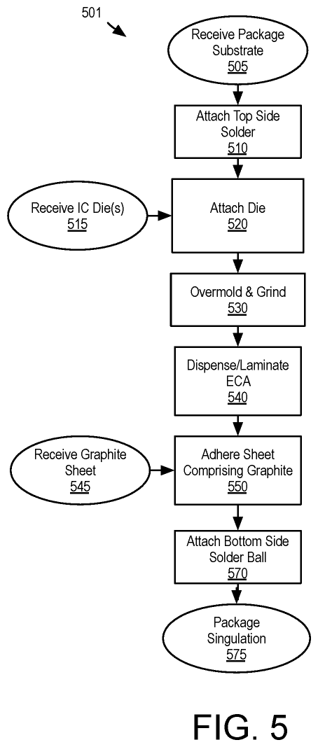

The IC packages described above may be assembled and/or fabricated with one or more of the features or attributes provided in accordance with various embodiments. A number of different assembly and/or fabrication methods may be practiced to generate an IC package having one or more of the features or attributes described above. FIG. 5 illustrates a flow diagram of assembly methods 501 suitable for packaging an IC die that is at least partially covered with an EMI shielding heat spreader comprising graphite, in accordance with some embodiments. Methods 501 may be employed to generate any of the IC packages 101-103 or 401, for example.

Assembly methods 501 begin at block 505 where a package substrate, interposer or other package material preform to which IC die may be attached is received as an input to the assembly methods. The package substrate may include, for example one or more metallized redistribution levels (RDL) embedded within dielectric material(s). In some embodiments, the RDL includes, or is connected to one or more metal features that protrude a predetermined z-height and may be subsequently electrically connected to a package level heat spreading material during package assembly methods 501.

Methods 501 continue at block 510 where solder features are attached to a first side (e.g., top side) of the package substrate that was received at block 505. Any top-side solder attachment process (e.g., ball attach, paste dispense, etc.) may be practiced at block 510. In some embodiments where the RDL lacks metal protrusions suitable to connecting to a heat spreading material, first solder features of a first, smaller, diameter are applied to a center portion of the package while second solder features having a second, larger, diameter are applied to a peripheral portion of the package. The second solder features provided during the IC package assembly may subsequently electrically interconnect a heat spreading material to a metallization within the package, for example. In some alternative embodiments, for example where the IC package has a relatively large area, a package stiffener (e.g., discrete metal frame) may be affixed to the package substrate before or after block 510, for example by pick-and-place, or a reel-to-reel taped-based transfer process.

At block 515, IC die are received as an input to the IC package assembly methods. The IC die received may be any IC die having circuit I/Os known to be suitable for the various blocks described herein as components of assembly methods 501. For example, an IC die received at block 515 may have any of the integrated circuits described elsewhere herein (e.g., wireless radio circuits, microprocessor circuits, etc.). The IC die may be received from an IC chip or wafer manufacturer, for example. The IC die received may have been singulated and electrically tested, for example according to any suitable die prep and e-test process.

Methods 501 continue at block 520 where IC die are attached to a package (substrate) material comprising RDL metallization. Any die attach technique known in the art may be employed at block 520. In some examples, a flip chip process is employed where top-side solder features applied at block 510 are reflowed to couple the IC die to the package RDL to arrive at an IC die-package RDL structure similar to that illustrated and described elsewhere herein, for example. In some embodiments, the IC die is coupled to the first solder features of smaller diameter while second solder features of larger diameter remain attached only to the package substrate (i.e., unattached to the IC die). In other embodiments, where the package RDL includes protruding metallization feature(s), the IC die may be positioned to be surrounded by these features. In other embodiments, where the package includes a stiffener, the IC die may be positioned to be surrounded by the stiffener.

At block 530 any suitable package overmold process may be practiced to apply a dielectric package material around and over the attached IC die, covering the IC die as well as the peripheral portion of the package material comprising solder feature(s), RDL metallization, and/or package stiffener. In further embodiments, block 530 further comprises any technique known to be suitable for exposing the IC die (e.g., inactive back-side of the IC die). For example, a package molding grind and/or polish process may be practiced to partially remove and/or planarize package material to expose the IC die backside.

Methods 501 continue at block 540 where an interface material is dispensed or laminated over the exposed IC die surface and over a planarized surface of package material. In some embodiments, a fluid material comprising metal particles (e.g., conductive ink) is applied over the package assembly with any liquid dispense suitable for the fluid (e.g., spraying or jetting). The fluid may further include one or more adhesives, for example. In some embodiments, the interface material is to be applied both over the exposed IC die surface and also over solder feature(s), package metallization feature(s), or package stiffener(s) present at the periphery surrounding the IC die. For lamination embodiments, interface material applied at block 540 may be delivered as part of a preform that further includes a sheet of material comprising graphite. For example a sheet of graphite may include an adhesive layer.

At block 545 a sheet of material comprising graphite is received. The material sheet, as received, may include a carrier to which the material comprising graphite is temporarily adhered, for example on a reel of tape. Alternatively, the sheet may be a discrete sheet of predominantly graphite (i.e., a discrete graphite sheet). The material sheet may have any dimension, for example, in a wafer-level assembly process, the material sheet may have an area large enough to cover a plurality of IC die package assemblies arrayed together in a reconstituted wafer. The material sheet may be part of a preform that further includes an electrically conductive adhesive interface material, for example including metal particles and one or more adhesives.

At block 550, the graphite sheet received at block 545 is placed in contact with the interface material. For example, a lamination machine may apply a discrete graphite sheet onto a plurality of IC package assemblies in a wafer-level process. In another example, a reel-to-reel process is employed to separately transfer a plurality of graphite sheets from a first carrier (e.g., a first tape reel) to IC packages supported by another carrier (e.g., a second tape reel). Following placement of the graphite sheet, the interface material may be cured and/or dried in the presence of any suitable curing or drying agent to complete an adhesive bond between the interface material and the graphite sheet. Following any such cure, the interface material has at least an electrical conductivity exceeding that of the underlying package material applied at block 530. As described elsewhere herein, the interface material may also have a thermal conductivity greater than that of the underlying package material applied at block 530. A portion of the interface material contacting electrical interconnects at the package periphery may serve to electrically interconnect the sheet of material comprising graphite to a voltage plane of the package. As such, any solder features at the package periphery need not be reflowed subsequent to application of the interface material (e.g., at block 540).

Following block 550, the IC package is ready for any further package-level assembly techniques known to be suitable for interfacing the IC package to a system-level assembly. In the illustrated example, methods 501 continue at block 570 where solder features are applied, for example to a bottom side of the package. In some examples, any suitable solder ball attach process is practiced. In other examples, a solder paste process is practiced.

Assembly methods 501 are completed at block 575 where IC packages are singulated, for example by cutting, laser ablating, or otherwise milling through the various package materials present at a periphery of an IC package. In some embodiments, block 575 entails cutting through at least a sheet of heat spreading material comprising graphite and an underlying dielectric package material. In some further embodiments, block 575 entails cutting through at least a sheet of heat spreading material comprising graphite, an underlying dielectric package material, and an interface material therebetween.

Once singulated, an IC package may be further assembled into any known computing system or platform. Any known system-level assembly processes may be practiced, for example, where solder balls on the bottom side of the package are interconnected to a host component (e.g., a printed circuit board or other system-level component). In some embodiments, a solder feature on the bottom side of the package electrically interconnected to a EMI shield heat spreader is further electrically coupled to a ground voltage plane of the system-level component.

Notably, the package-level techniques and structure described above that include a EMI shielding heat spreader that may further interface with system level thermal solutions to dissipate heat away from the package, for example improving burst time parameters of a packaged IC device. Any suitable system level thermal management components may be applied over the sheet of heat spreading material comprising graphite. For example, a pad of thermal interface material (TIM) may be applied over the sheet of heat spreading material comprising graphite. A system-level heat spreader and/or heat sink may also be applied over the sheet of heat spreading material comprising graphite.

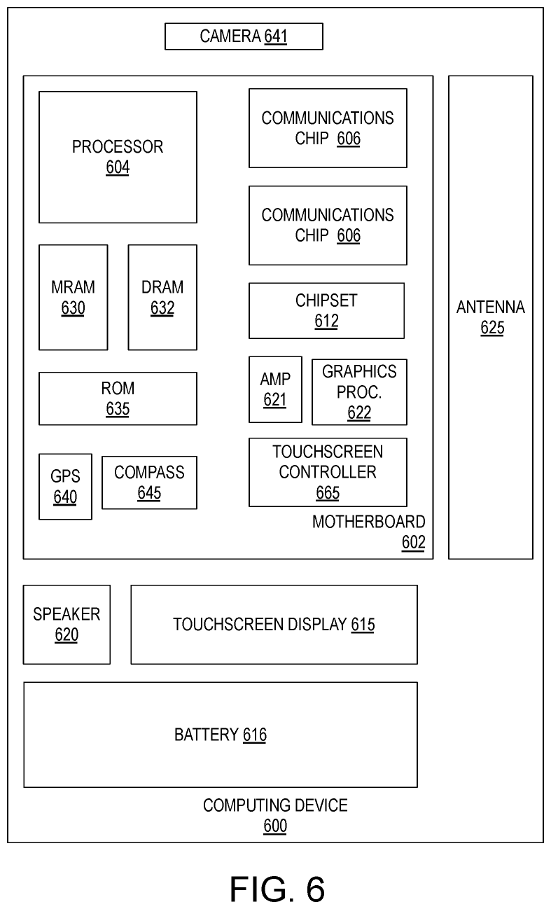

FIG. 6 is a functional block diagram of an electronic computing device 600, in accordance with an embodiment of the present invention. Device 600 further includes a motherboard 602 hosting a number of components, such as, but not limited to, a processor 604 (e.g., an applications processor). Processor 604 may be physically and/or electrically coupled to motherboard 602. In some examples, processor 604 includes an integrated circuit die packaged with an EMI shielding heat spreader comprising graphite, for example as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 606 may also be physically and/or electrically coupled to the motherboard 602. In further implementations, communication chips 606 may be part of processor 604. Depending on its applications, computing device 600 may include other components that may or may not be physically and electrically coupled to motherboard 602. These other components include, but are not limited to, volatile memory (e.g., DRAM 632), non-volatile memory (e.g., ROM 635), flash memory (e.g., NAND or NOR), magnetic memory (MRAM 630), a graphics processor 622, a digital signal processor, a crypto processor, a chipset 612, an antenna 625, touchscreen display 615, touchscreen controller 665, battery 616, audio codec, video codec, power amplifier 621, global positioning system (GPS) device 640, compass 645, accelerometer, gyroscope, speaker 620, camera 641, and mass storage device (such as hard disk drive, solid-state drive (SSD), compact disk (CD), digital versatile disk (DVD), and so forth), or the like. In some exemplary embodiments, at least one of the functional blocks noted above comprise an IC package with an EMI shielding heat spreader comprising graphite, for example as described elsewhere herein.

Communication chips 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 606 may implement any of a number of wireless standards or protocols, including but not limited to those described elsewhere herein. As discussed, computing device 600 may include a plurality of communication chips 606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

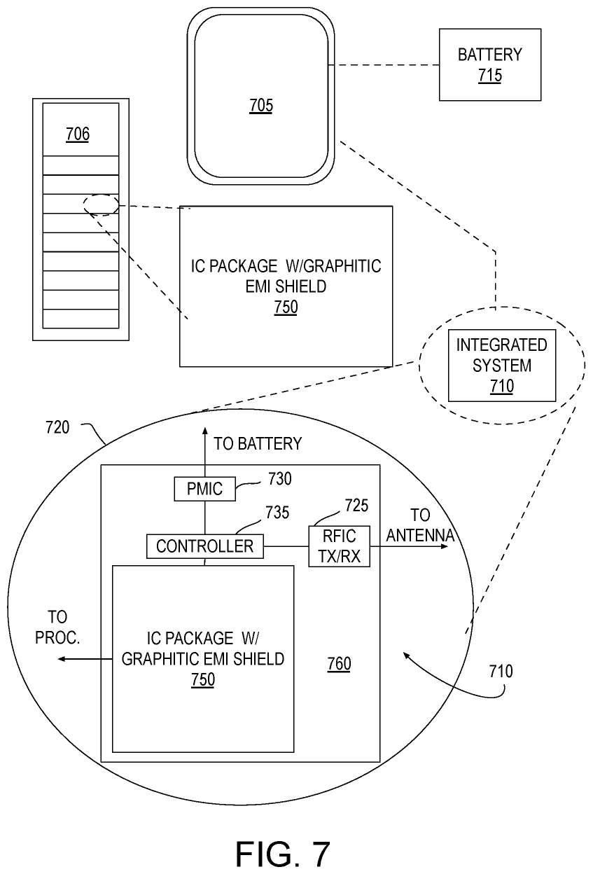

FIG. 7 illustrates a mobile computing platform and a data server machine employing an IC package with an EMI shielding heat spreader comprising graphite, for example as described elsewhere herein. Computing device 600 may be found inside platform 705 or server machine 706, for example. The server machine 706 may be any commercial server, for example including any number of high-performance computing platforms disposed within a rack and networked together for electronic data processing, which in the exemplary embodiment includes a packaged SoC 750 that further includes an EMI shielding heat spreader comprising graphite, for example as described elsewhere herein. The mobile computing platform 705 may be any portable device configured for each of electronic data display, electronic data processing, wireless electronic data transmission, or the like. For example, the mobile computing platform 705 may be any of a tablet, a smart phone, laptop computer, etc., and may include a display screen (e.g., a capacitive, inductive, resistive, or optical touchscreen), a chip-level or package-level integrated system 710, and a battery 715.

Whether disposed within the integrated system 710 illustrated in the expanded view 720, or as a stand-alone chip within the server machine 706, IC package 750 may include an EMI shielding heat spreader comprising graphite, for example as described elsewhere herein. IC package 750 may be further coupled to a board, a substrate, or an interposer 760 along with, one or more of a power management integrated circuit (PMIC) 730, RF (wireless) integrated circuit (RFIC) 725 including a wideband RF (wireless) transmitter and/or receiver (TX/RX) (e.g., including a digital baseband and an analog front end module further comprises a power amplifier on a transmit path and a low noise amplifier on a receive path), and a controller 735.

Functionally, PMIC 730 may perform battery power regulation, DC-to-DC conversion, etc., and so has an input coupled to battery 715 and with an output providing a current supply to other functional modules. As further illustrated, in the exemplary embodiment, RFIC 725 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example the above embodiments may include specific combinations of features as further provided below.

What is claimed is:

1. An integrated circuit (IC) package, comprising:
a die comprising an integrated circuit,
a dielectric material between a sidewall of the die and an electrical interconnect;
a first electrically conductive material over the die and the dielectric material; and
a second electrically conductive material over the first electrically conductive material, wherein the second electrically conductive material comprises graphite, and wherein at least one of the first or second electrically conductive materials is in contact with the electrical interconnect.

2. The IC package of claim 1, wherein the second electrically conductive material comprises a graphite sheet having an area exceeding that of the die.

3. The integrated circuit package of claim 2, wherein the second electrically conductive material has anisotropic thermal conductivity with a highest thermal conductivity in a plane substantially parallel to a surface of the die.

4. The integrated circuit package of claim 3, wherein further comprising a metal embedded within an opening in the graphite sheet, the opening located over the die.

5. The integrated circuit package of claim 1, wherein:
the dielectric material has a thermal conductivity less than 4 W/mK; and
the second electrically conductive material has a thermal conductivity of at least 400 W/mK.

6. The integrated circuit package of claim 1, wherein the first electrically conductive material comprises a composite, the composite comprising conductive filler particles within a matrix material.

7. The integrated circuit package of claim 5, wherein the matrix material comprises at least one of an epoxy or silicone.

8. The integrated circuit package of claim 1, wherein:
a first surface of the die is interconnected to one or more first metallization traces within the package;
the die has four sidewall surfaces intersecting the first surface of the die and a second surface of the die;
the dielectric material is in contact with the four sidewall surfaces;
the first electrically conductive material is in contact with the second surface of the die; and
the electrical interconnect is coupled to one or more second metallization traces within the package.

9. The integrated circuit package of claim 8, wherein the second surface of the die comprises one or more surface recesses, and wherein the first electrically conductive material is within the one or more surface recesses.

10. The integrated circuit package of claim 8, wherein the electrical interconnect comprises at least one of a solder feature, a pillar or trace comprising copper, or a package stiffener comprising iron.

11. The integrated circuit package of claim 10, wherein the electrical interconnect forms a perimeter about the four sidewall surfaces of the die, and wherein the solder feature is one of a plurality of solder features spaced along the perimeter, the pillar is one of a plurality of pillars spaced along the perimeter, or the trace or stiffener is continuous along the perimeter.

12. A computer system, comprising:
a power supply;
a system component comprising interconnect circuitry; and
one or more integrated circuit packages coupled to the system component, wherein at least one of the integrated circuit packages further comprises:
an IC die;
a dielectric material between a sidewall of the die and an electrical interconnect;
a first electrically conductive material over the die and the dielectric material; and
a second electrically conductive material over the first electrically conductive material, wherein the second electrically conductive material comprises graphite, and wherein at least one of the first or second electrically conductive materials is in contact with the electrical interconnect.

13. The computer system of claim 12, wherein:
the at least one of the integrated circuit packages further comprises a package substrate, a center portion of the package substrate coupled to a first surface of the IC die through a plurality of solder features;
the dielectric material is over a perimeter portion of the package substrate; in contact with a plurality of sidewall surfaces of the IC die, and in contact with the electrical interconnect;
the first electrically conductive material is in contact with the second dielectric material; and
the second electrically conductive material is adhered to a second surface of the IC die with the first electrically conductive material.

14. The computer system of claim 13, wherein the electrical interconnect is to be coupled to a ground voltage plane of the system component.

15. The computer system of claim 14, wherein:
the electrical comprises one of a plurality of solder features spaced along a perimeter of the IC die, one of a plurality of pillars spaced along the perimeter, or the trace or stiffener is continuous along the perimeter; and
the graphite sheet is coupled to the reference voltage through the electrical interconnect.

16. A method of assembling an integrated circuit (IC) package, the method comprising:
receiving an IC die;
coupling the IC die to one or more package metallization levels;
forming a dielectric material between a sidewall surface of the IC die and one or more electrical interconnects that are coupled to at least one of the package metallization levels;
applying an electrically conductive adhesive over the IC die, over the dielectric material, and over the electrical interconnects; and
affixing, with the adhesive, an electrically conductive material comprising graphite over the IC die and the electrical interconnects.

17. The method of claim 16, further comprising:
receiving a package substrate comprising the package metallization levels;
attaching solder features to the package substrate; and
wherein:
coupling the IC die to the one or more package metallization levels comprises reflowing the solder features to contact a first surface of the IC die; and
the electrical interconnects comprise at least one of solder features attached to the package substrate, or metal features of the package substrate.

18. The method of claim 16, wherein the dielectric material is applied subsequent to coupling the IC die to the package substrate.

19. The method of claim 16, wherein:
applying an electrically conductive adhesive comprises:
dispensing a liquid over the IC die, the dielectric material, and the electrical interconnects, the liquid comprising conductive particles; and
at least partially curing the liquid; and
affixing the electrically conductive material with the adhesive comprises laminating the graphite sheet to the electrically conductive adhesive.

20. The method of claim 17, wherein forming the dielectric material comprises molding an epoxy, having a thermal conductivity at least two orders of magnitude smaller than that of the electrically conductive material, around a perimeter of the IC die, the epoxy also surrounding electrical interconnects.
